(19) United States
(12) Patent Application Publication
(10) Pub. No.: US 2019/0029130 A1
(43) Pub. Date: Jan. 24, 2019

(54) DISPLAY DEVICE

(71) Applicant: FANUC CORPORATION, Yamanashi (JP)

(72) Inventors: Yasumichi Sakoda, Yamanashi-ken (JP); Hiroyuki Kataya, Yamanashi-ken (JP)

(73) Assignee: FANUC CORPORATION, Yamanashi (JP)

(21) Appl. No.: 16/039,382

(22) Filed: Jul. 19, 2018

(30) Foreign Application Priority Data
Jul. 20, 2017 (JP) 2017-140476

(51) Int. Cl. H05K 5/00

(52) U.S. Cl. CPC H05K 5/0017

(57) ABSTRACT

A display device includes: a sheet attached to a display panel and a display surface side of a housing; an opening formed on the display surface side of the housing so as to allow access to an interface terminal provided in the housing; and a lid covering the opening. The display panel and the display surface side of the housing are sectioned into a first region to which the sheet is attached and a second region with no sheet attached, with respect to a longitudinal direction of the display panel. The first region is an area including the display panel and part of the housing. The opening is arranged in the second region.

### CROSS-REFERENCE TO RELATED APPLICATION

This application is based upon and claims the benefit of priority from Japanese Patent Application No. 2017-140476 filed on Jul. 20, 2017, the contents of which are incorporated herein by reference.

### BACKGROUND OF THE INVENTION

### Field of the Invention

The present invention relates to a display device having a sheet attached to the display surface side thereof.

### Description of the Related Art

Japanese Laid-Open Patent Publication No. 02-006987 discloses a front decorative structure for improving the aesthetic appearance of the front part of an electrical appliance having a display device and buttons on the front surface thereof. Briefly explaining, the front decorative structure is composed of a colorless transparent first sheet on which a display pattern is printed on the rear surface thereof in an area opposing buttons and a colored translucent second sheet having opaque printing other than a window opposing the display device with its one side attached to the rear side of the first sheet and the other side attached to the front surface of the electrical appliance.

### SUMMARY OF THE INVENTION

However, the configuration of Japanese Laid-Open Patent Publication No. 02-006987, needs to perform attaching twice, that is, the attachment of the first sheet to the second sheet and the attachment of the second sheet to the front surface of the electrical appliance, which requires time and effort, resulting in being costly.

It is therefore an object of the present invention to provide a display device that can reduce the number of steps for sheet attachment while improving aesthetic appearance.

An aspect of the present invention resides in a display device including a rectangular display panel and a housing covering an outer peripheral portion and a rear surface of the display panel, comprising: a sheet attached to the display panel and the display surface side of the housing; an opening formed on the display surface side of the housing so as to allow access to an interface terminal provided in the housing; and a lid covering the opening, wherein: the display panel and the display surface side of the housing are sectioned into a first region to which the sheet is attached and a second region with no sheet attached, with respect to a longitudinal direction or a short side direction of the display panel; the first region is an area including the display panel and part of the housing; and the opening is arranged in the second region.

According to the present invention, the aesthetic appearance of the display surface side of the display device is improved while the number of steps for attaching the sheet is reduced, and so is the cost.

The above and other objects, features, and advantages of the present invention will become more apparent from the following description when taken in conjunction with the accompanying drawings in which a preferred embodiment of the present invention is shown by way of illustrative example.

### BRIEF DESCRIPTION OF THE DRAWINGS

FIG. 1 is a front view of a display device according to a first embodiment;

FIG. 2 is a front view showing an example of a display device in Variational Example 1 of the first embodiment;

FIG. 3 is a front view showing an example (Example 1) of a display device in Variational Example 2 of the first embodiment;

FIG. 4 is a front view showing an example (Example 2) of a display device in Variational Example 2 of the first embodiment;

FIG. 5 is a front view of a display device of a second embodiment;

FIG. 6 is a front view showing an example of a display device in Variational Example 1 of the second embodiment;

FIG. 7 is a front view showing an example (Example 1) of a display device in Variational Example 2 of the second embodiment; and

FIG. 8 is a front view showing an example (Example 2) of a display device in Variational Example 2 of the second embodiment.

### DESCRIPTION OF THE PREFERRED EMBODIMENTS

Next, the display devices according to the present invention will be detailed by describing preferred embodiments with reference to the accompanying drawings.

### First Embodiment

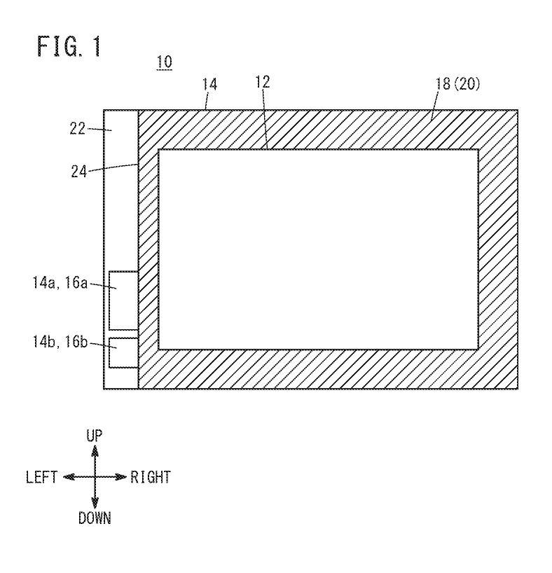

FIG. 1 is a front view of a display device (display unit) 10 according to a first embodiment. The display device 10 includes a rectangular display panel (liquid crystal panel, organic EL panel, etc.) 12 and a housing 14 that covers the outer peripheral portion and the rear side of the display panel 12. In the first embodiment, right and left and up and down will be explained according to the arrows in the left-right direction and the up-down direction shown in FIG. 1. Therefore, the horizontal direction is the longitudinal direction of the display panel 12, and the vertical direction is the short side direction of the display panel 12.

The display panel 12 displays images and the like. A touch panel (not shown) is provided over the display surface of the display panel 12.

In the housing 14, an SD terminal and a USB terminal (not shown) which are interface terminals are provided, and in order to enable the operator to access the SD terminal and the USB terminal, the housing 14 has openings 14a, 14b formed on the display surface side of the display device 10. Attached to these openings 14a, 14b are detachable lids 16a, 16b covering the openings 14a, 14b, respectively. The SD terminal is arranged in the opening 14a, whereas the USB terminal is arranged in the opening 14b. Therefore, by removing the lids 16a, 16b from the openings 14a, 14b, the openings 14a, 14b are exposed. As a result, the operator (user) can access the SD terminal and the USB terminal arranged in the openings 14a, 14b. In order to simplify the explanation below, the lids 16a, 16b which are attached to the openings 14a, 14b are simply referred to as lids 16a, 16b.

In the example shown in FIG. 1, the openings 14a, 14b and the lids 16a, 16b are arranged on one end side (the left end side) of the housing 14 in the longitudinal direction of the display device 10, that is, on the left side of the display panel 12. In the example shown in FIG. 1, the openings 14a, 14b and the lids 16a, 16b are arranged on the lower side with respect to the short side direction (vertical direction) of the housing 14. However, the openings 14a, 14b and the lids 16a, 16b may be disposed in the middle part or the upper part. The opening 14a and the lid 16a are arranged in the position upper than the opening 14b and the lid 16b.

A sheet 18 is attached to the display surface side (the display panel 12 and the display surface side of the housing 14) of the display device 10 so as not to cover the lids 16a, 16b. For convenience, the region to which the sheet 18 is attached is referred to as a first region 20, and the region where the sheet 18 is not attached is referred to as a second region 22. In FIG. 1, the area of the housing 14 in the first region 20 is represented by oblique hatching. That is, the area of the sheet 18 attached to the housing 14 is indicated by oblique hatching.

The first region 20 is an area including the display panel 12 and part of the housing 14, and the openings 14a, 14b and lids 16a, 16b are arranged in the second region 22. The second region 22 is an area including at least part of the housing 14 on the left side of the display panel 12. That is, the display surface side of the display device 10 is divided into two regions, namely, the first region 20 and the second region 22, with respect to the longitudinal direction of the display panel 12. Therefore, the second region 22 includes the entire range of the display device 10 (the housing 14) with respect to the vertical direction, and the first region 20 includes the entire range of the display device 10 (the display panel 12 and the housing 14) with respect to the vertical direction. The first region 20 is a region including at least the display panel 12 and part of the housing 14 located on the right side, upper side and lower side of the display panel 12.

In the first embodiment, since the sheet 18 has a quadrangular shape, the boundary line, designated at 24, between the first region 20 and the second region 22 extends straight in the vertical direction (the short side direction of the display panel 12). This boundary line 24 is located on the left side of the display panel 12. With the boundary line 24 as a border, the left side is the second region 22, and the right side is the first region 20, both being quadrangular (specifically, rectangular).

Note that the boundary line 24 may be located on the left end of the display panel 12. That is, the boundary line 24 may be on the border (the border extending in the vertical direction) between the display panel 12 and the housing 14 on the left side of the display panel 12.

In the first embodiment, the first region 20 and the second region 22 are configured such that one side (one side on the right side of each of the lids 16a, 16b) of each of the lids 16a, 16b coincides with the boundary line 24. This makes it possible to shorten the dimension of the second region 22 in the width direction (the left-to-right direction).

In this way, since the sheet 18 is not attached to the second region 22 where the openings 14a, 14b and the lids 16a, 16b are provided, the work of attaching the sheet 18 to the display device 10 can be simplified, resulting in reduction in the number of steps for attachment, and hence being low in cost. In addition, the display surface side (the display panel 12 and the display surface side of the housing 14) of the display device 10 is sectioned into the first region 20 to which the sheet 18 is attached and the second region 22 with no sheet 18 attached, with respect to the longitudinal direction of the display panel 12, so that the aesthetic appearance is improved.

The area of the sheet 18 corresponding to the display panel 12 (the area to be attached to the display panel 12) is transparent while the area of the sheet 18 corresponding to the housing 14 (the area to be attached to the housing 14) is colored with an opaque paint. That is, in FIG. 1, the area represented by oblique hatching is the colored area. Since the sheet 18 is made of a material different from the material constituting the housing 14, the texture of the sheet 18 is different from that of the housing 14. In addition, since the housing 14 and the lids 16a, 16b are formed of the same material, they have the same color and texture. The colored part of the sheet 18 is different in color from the housing 14. Therefore, by attaching the sheet 18 to the first region 20, the color changes at the boundary line 24 from one region to the other, so that the display surface side of the display device 10 has a two-toned appearance. Thus, the aesthetic appearance of the display surface side of the display device 10 is further improved.

Conventionally, in the sheet to be attached on the display surface side of the display device 10, the portion corresponding to the lids 16a, 16b was cut out so as to open the area. As a result, color, texture and the like differ only in the area of the lids 16a, 16b, and the aesthetic appearance deteriorates. Therefore, it is necessary to apply the sheet also to the lids 16a, 16b to match the color and texture with the area other than the lids 16a, 16b. This improves the aesthetic appearance, but it takes time and costs.

In the first embodiment, the display surface side of the display device 10 is sectioned into the first region 20 (region including the display panel 12) to which the sheet 18 is attached and the second region 22 where the sheet 18 is not attached, along the longitudinal direction of the display panel 12. As to the short side direction of the display panel 12, the second region 22 in which the openings 14a, 14b and the lids 16a, 16b are provided is formed so as to extend the full range of the housing 14. This improves the aesthetic appearance of the display surface side of the display device 10 while reducing the number of steps for attaching the sheet 18, resulting in reduction in cost.

### Variational Examples of First Embodiment

The first embodiment can be modified as follows. The same components as those in the first embodiment are allotted with the same reference numerals, and only the differences will be described.

### Variational Example 1

In Variational Example 1, first region 20 and the second region 22 are formed such that the lids 16a, 16b do not contact the boundary line 24.

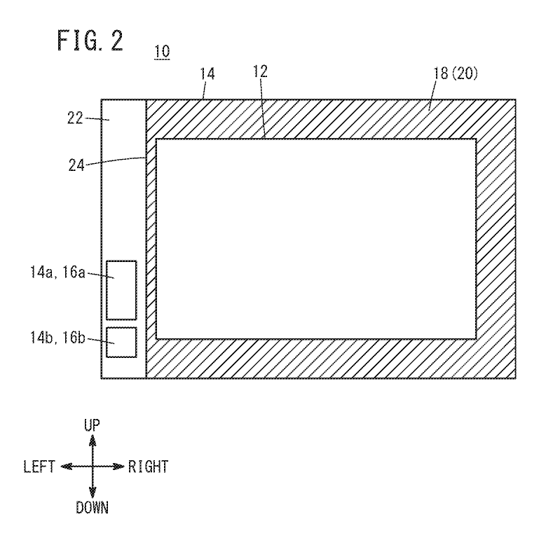

FIG. 2 is a front view showing an example of the display device 10 in Variational Example 1 of the first embodiment. As can be seen from FIG. 2, the lids 16a, 16b are located on the left side of the boundary line 24 with a predetermined distance apart from the boundary line 24 extending straight in the vertical direction.

In this way, even if the lids 16a, 16b do not contact the boundary line 24, the aesthetic appearance of the display surface side of the display device 10 is improved while the number of steps for attaching the sheet 18 is reduced with a reduction in cost.

### Variational Example 2

In Variational Example 2, the first region 20 and the second region 22 are formed so that the boundary line 24 is a line composed of curves, a line composed of a plurality of straight lines, or a line composed of a combination of curves and straight lines.

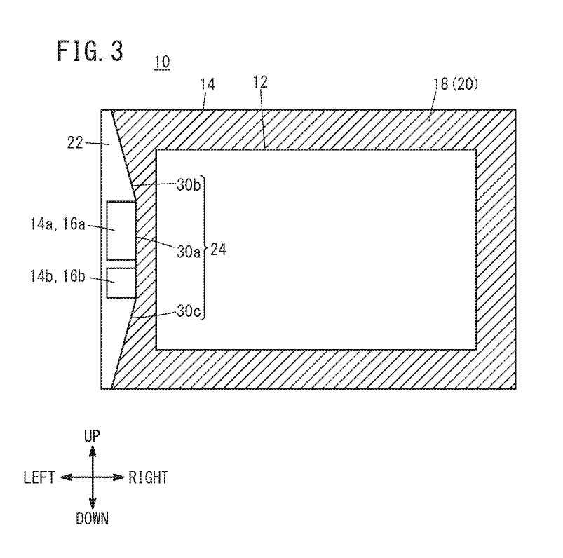

FIG. 3 is a front view showing an example (Example 1) of the display device 10 in Variational Example 2 of the first embodiment. As shown in FIG. 3, the openings 14a, 14b and the lids 16a, 16b are arranged in the housing 14 on the left side of the display panel 12, around the middle part with respect to the short side direction (vertical direction). The boundary line 24 is composed of a line 30a extending vertically so as to be in contact with one side of each of the lids 16a, 16b (the right side of each of the lids 16a, 16b), a line 30b extending from the upper end of the line 30a, obliquely upward and leftward (in a direction away from the display panel 12) and a line 30c extending from the lower end of the line 30a, obliquely downward and leftward (in a direction away from the display panel 12). Thus, both the first region 20 and the second region 22 are changed in shape, and the shape of the sheet 18 is also changed.

Though, in the example shown in FIG. 3, the line 30a of the boundary line 24 is in contact with one side of each of the lids 16a, 16b, the lids 16a, 16b may not necessarily contact the line 30a, as in Variational Example 1. In the example shown in FIG. 3, the openings 14a, 14b and the lids 16a, 16b are disposed around the middle part with respect to the short side direction of the display device 10, but they may be disposed in the upper part or in the lower part. Also in this case, the shape of the boundary line 24 may be arbitrarily changed in conformity with the layout of the lids 16a, 16b.

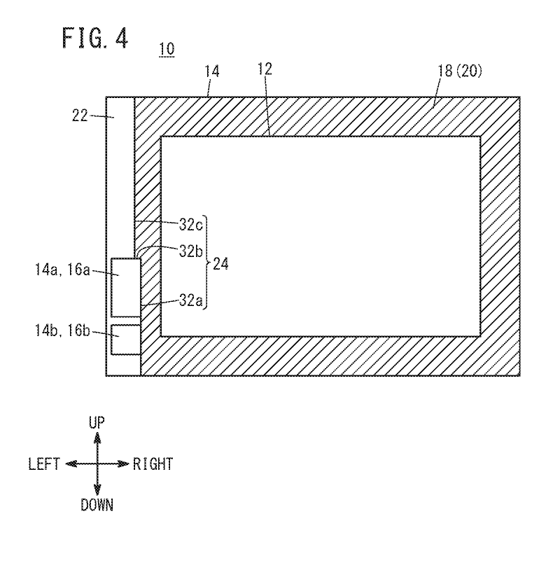

FIG. 4 is a front view showing an example (Example 2) of the display device 10 in Variational Example 2 of the first embodiment. As shown in FIG. 4, the boundary line 24 is composed of a line 32a extending vertically so as to be in contact with one side of each of the lids 16a, 16b (the right side of each of the lids 16a, 16b), a line 32b extending leftward from the upper end of the line 32a so as to be in contact with part of one side of the upper side of the lid 16a and a line 32c extending upward from the left end of the line 32b. Thus, both the first region 20 and the second region 22 are changed in shape, and the shape of the sheet 18 is also changed.

In the example shown in FIG. 4, the openings 14a, 14b and the lids 16a, 16b are disposed in the lower part with respect to the short side direction of the display device 10, but they may be disposed around the middle part, or in the upper part. Also in this case, the shape of the boundary line 24 may be arbitrarily changed in conformity with the layout of the lids 16a, 16b.

Thus, the display surface side may be sectioned into the first region 20 and the second region 22 with respect to the longitudinal direction of the display panel 12 while the second region 22 is formed so as to extend the full range of the housing 14 with respect to the short side direction of the display panel 12. Also in Variational Example 2, the aesthetic appearance of the display surface side of the display device 10 is improved while the number of steps for attaching the sheet 18 is reduced, and so is the cost.

It should be noted that the case where the boundary line 24 is a line composed of curves, or a line composed of a combination of curves and straight lines, can be similarly handled.

### Variational Example 3

Though in the first embodiment and Variational Examples 1 and 2, the openings 14a, 14b and the lids 16a, 16b are disposed in the left side part with respect to the longitudinal direction of the display device 10 (that is, in the housing 14 on the left side of the display panel 12), they may be arranged in the right side part with respect to the longitudinal direction of the display device 10 (that is, in the housing 14 on the right side of the display panel 12).

### Second Embodiment

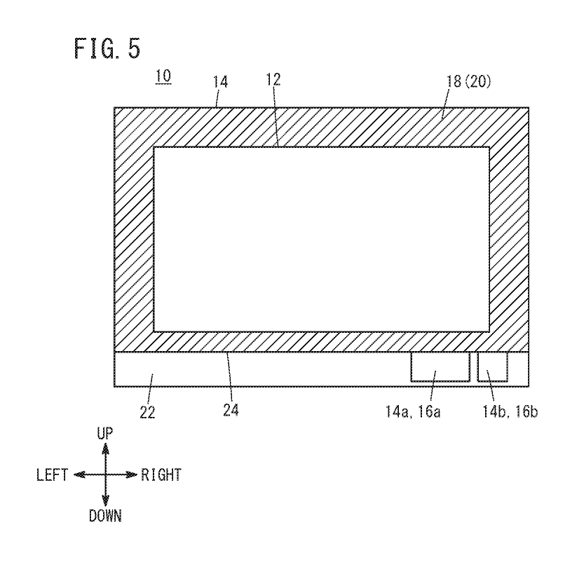

FIG. 5 is a front view of a display device 10 according to the second embodiment. The second embodiment is different from the first embodiment in that the display surface side of the display device 10 is sectioned into a first region 20 and a second region 22 with respect to the short side direction of the display panel 12. The same components as those of the first embodiment are allotted with the same reference numerals, and only differences will be described. In FIG. 5 as well, the area of the housing 14 in the first region 20 is represented by oblique hatching. That is, the area of the sheet 18 attached to the housing 14 is indicated by oblique hatching.

In the example shown in FIG. 5, the openings 14a, 14b and the lids 16a, 16b are arranged on one end side (lower end side) with respect to the short side direction of the display device 10, that is, in the housing 14 on the lower side of the display panel 12. In the example shown in FIG. 5, the openings 14a, 14b and the lids 16a, 16b are disposed on the right side part with respect to the longitudinal direction of the housing 14, but they may be arranged around the central part or in the left side part. The opening 14a and the lid 16a are arranged on the left side of the opening 14b and the lid 16b.

The second region 22 is an area including at least part of the housing 14 on the lower side of the display panel 12 and forms an area including the entire range of the display device 10 (housing 14) with respect to the lateral direction. The openings 14a, 14b and lids 16a, 16b are arranged in the second region 22. The first region 20 is a region including at least the display panel 12, and part of the housing 14 located on the left side, upper side and right side of the display panel 12.

Also in the second embodiment, since the sheet 18 has a quadrangular shape, the boundary line 24 between the first region 20 and the second region 22 extends straight in the lateral direction (the longitudinal direction of the display panel 12). This boundary line 24 is located on the lower side of the display panel 12. With the boundary line 24 as a border, the lower side is the second region 22, and the upper side is the first region 20, and both being quadrangular (specifically, rectangular).

Note that the boundary line 24 may be located on the lower end of the display panel 12. That is, the boundary line 24 may be on the border (the border extending in the lateral direction) between the display panel 12 and the housing 14 on the lower side of the display panel 12.

In the second embodiment as well, the first region 20 and the second region 22 are defined such that one side (one side on the upper side of each of the lids 16a, 16b) of each of the lids 16a, 16b coincides with the boundary line 24. This makes it possible to shorten the dimension of the second region 22 in the width direction (the dimension in the short side direction of the display panel 12).

The area of the sheet 18 to be attached to the display surface side of the display device 10 corresponding to the display panel 12 is transparent while the area of the sheet 18 corresponding to the housing 14 is colored with an opaque paint. Further, the texture of the sheet 18 is different from the texture of the housing 14, and the colored part of the sheet 18 is different in color from the housing 14.

Thus, also in the second embodiment, the aesthetic appearance of the display surface side of the display device 10 is improved while the number of steps for attaching the sheet 18 is reduced, and so is the cost.

### Variational Examples of Second Embodiment

The second embodiment can be modified as follows. The same components as those in each of the above-described embodiments are allotted with the same reference numerals, and only differences will be described.

### Variational Example 1

In Variational Example 1, the first region 20 and the second region 22 are formed such that the lids 16a, 16b do not contact the boundary line 24.

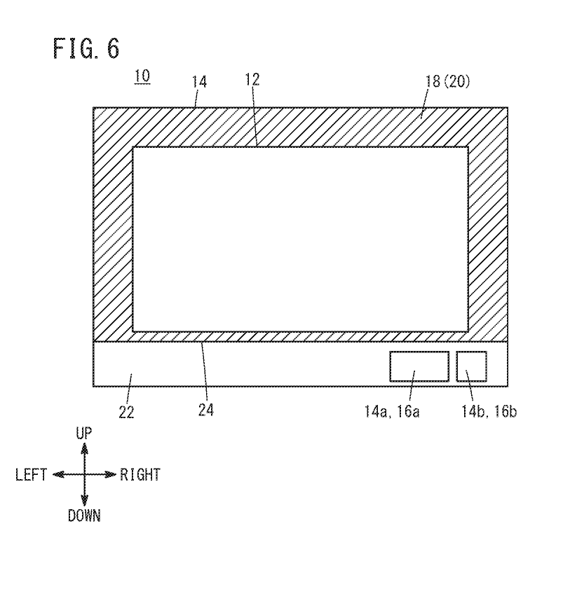

FIG. 6 is a front view showing an example of the display device 10 in Variational Example 1 of the second embodiment. As can be seen from FIG. 6, the lids 16a, 16b are located below the boundary line 24 with a predetermined distance apart from the boundary line 24 extending straight in the lateral direction.

In this way, even if the lids 16a, 16b do not contact the boundary line 24, the aesthetic appearance of the display surface side of the display device 10 is improved while the number of steps for attaching the sheet 18 is reduced with a reduction in cost.

### Variational Example 2

In Variational Example 2, the first region 20 and the second region 22 are formed so that the boundary line 24 is a line composed of curves, a line composed of a plurality of straight lines, or a line composed of a combination of curves and straight lines.

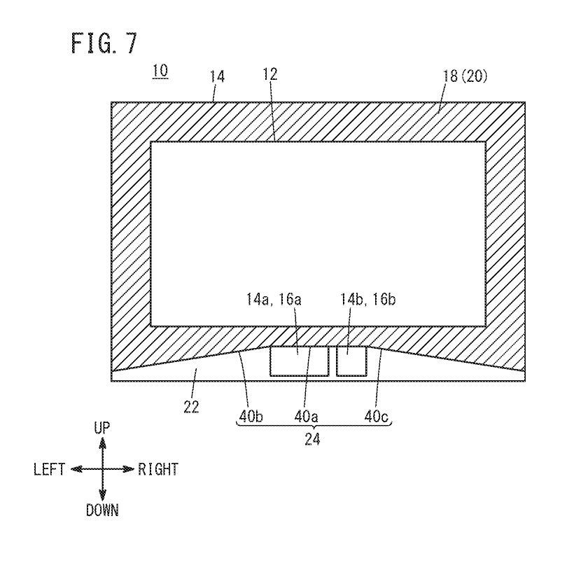

FIG. 7 is a front view showing an example (Example 1) of the display device 10 in Variational Example 2 of the second embodiment. As shown in FIG. 7, the openings 14a, 14b and the lids 16a, 16b are arranged in the housing 14 under the display panel 12 in the center with respect to the longitudinal direction (lateral direction). The boundary line 24 is composed of a line 40a extending laterally so as to be in contact with one side of each of the lids 16a, 16b (the upper side of each of the lids 16a, 16b), a line 40b extending from the left end of the line 40a, obliquely downward and leftward in a direction away from the display panel 12 and a line 40c extending from the right end of the line 40a, obliquely downward and rightward in a direction away from the display panel 12. Thus, both the first region 20 and the second region 22 are changed in shape, and the shape of the sheet 18 is also changed.

Though, in the example shown in FIG. 7, the line 40a of the boundary line 24 is in contact with one side of each of the lids 16a, 16b, the lids 16a, 16b may not necessarily contact the line 40a, as in Variational Example 1. In the example shown in FIG. 7, the openings 14a, 14b and the lids 16a, 16b are disposed in the center with respect to the longitudinal direction of the display device 10, but they may be arranged in the left side part, or in the right side part. Also in this case, the shape of the boundary line 24 may be arbitrarily changed in conformity with the layout of the lids 16a, 16b.

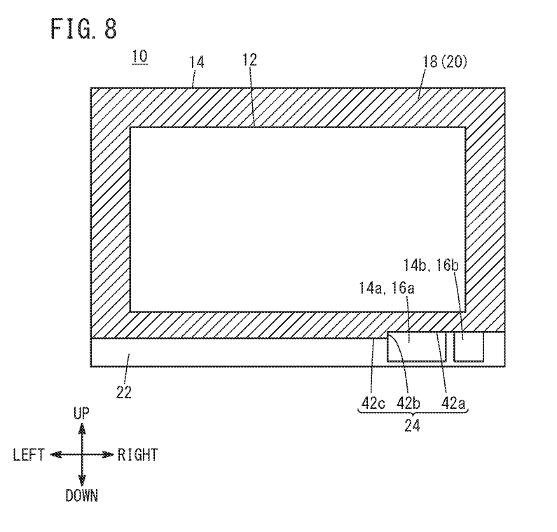

FIG. 8 is a front view showing an example (Example 2) of the display device 10 in Variational Example 2 of the second embodiment. As shown in FIG. 8, the boundary line 24 is composed of a line 42a extending laterally so as to be in contact with one side of each of the lids 16a, 16b (the upper side of each of the lids 16a, 16b) and a line 42b extending downward from the left end of the line 42a so as to be in contact with part of the left side of the lid 16a and a line 42c extending leftward from the lower end of the line 42b. Thus, both the first region 20 and the second region 22 are changed in shape, and the shape of the sheet 18 is also changed.

In the example shown in FIG. 8, the openings 14a, 14b and the lids 16a, 16b are arranged in the right side part with respect to the longitudinal direction of the display device 10, but they may be disposed in the center, or in the left side part. Also in this case, the shape of the boundary line 24 may be arbitrarily changed in conformity with the layout of the lids 16a, 16b.

Thus, the display surface side may be sectioned into the first region 20 and the second region 22 with respect to the short side direction of the display panel 12 while the second region 22 is formed so as to extend the full range of the housing 14 with respect to the longitudinal direction of the display panel 12. Also in Variational Example 2, the aesthetic appearance of the display surface side of the display device 10 is improved while the number of steps for attaching the sheet 18 is reduced, and so is the cost.

It should be noted that the case where the boundary line 24 is a line composed of curves, or a line composed of a combination of curves and straight lines can be similarly handled.

### Variational Example 3

In the second embodiment and Variational Examples 1 and 2, the openings 14a, 14b and the lids 16a, 16b are disposed in the lower part with respect to the short side direction of the display device 10 (that is, in the housing 14 under the display panel 12), they may be arranged in the upper part with respect to the short side direction of the display device 10 (that is, in the housing 14 above the display panel 12).

The present invention is not limited to the embodiments described above, and it goes without saying that the embodiments can be freely modified within a range that does not deviate from the essence and gist of the present invention as set forth in the appended claims.

### Technical Idea Obtained from Embodiments

Technical ideas that can be grasped from the above embodiments and Variational Examples are described below.

A display device (10) includes a rectangular display panel (12) and a housing (14) covering an outer peripheral portion and the rear surface of the display panel (12). The display device (10) includes: a sheet (18) attached to the display panel (12) and the display surface side of the housing (14); the opening (14a, 14b) formed on the display surface side of the housing (14) so as to allow access to the interface terminal provided in the housing (14); and the lid (16a, 16b) covering the opening (14a, 14b). The display panel (12) and the display surface side of the housing (14) are sectioned into a first region (20) to which the sheet (18) is attached and a second region (22) with no sheet (18) attached, with respect to the longitudinal direction or the short side direction of the display panel (12). The first region (20) is an area including the display panel (12) and part of the housing (14). The opening (14a, 14b) is arranged in the second region (22).

This improves the aesthetic appearance of the display surface side of the display device (10), reduces the number of steps for attaching the sheet (18), and reduces the cost.

The first region (20) and the second region (22) may be configured in a manner that one side of the lid (16a, 16b) attached to the opening (14a, 14b) is in contact with the boundary line (24) between the first region (20) and the second region (22). Thus, the aesthetic appearance of the display surface side of the display device (10) is further improved.

The boundary line (24) between the first region (20) and the second region (22) may be configured to extend straight. Thus, the aesthetic appearance of the display surface side of the display device (10) is further improved.

Of the sheet (18), the area to be attached to the display panel (12) may be transparent and the area to be attached to the housing (14) may be colored with a color different from that of the housing (14). Thus, the aesthetic appearance of the display surface side of the display device (10) is further improved.

The sheet (18) may have a texture different from that of the housing (14). Thus, the aesthetic appearance of the display surface side of the display device (10) is further improved.

What is claimed is:

1. A display device including a rectangular display panel and a housing covering an outer peripheral portion and a rear surface of the display panel, comprising:
a sheet attached to the display panel and the display surface side of the housing;
an opening formed on the display surface side of the housing so as to allow access to an interface terminal provided in the housing; and
a lid covering the opening, wherein:
the display panel and the display surface side of the housing are sectioned into a first region to which the sheet is attached and a second region with no sheet attached, with respect to a longitudinal direction or a short side direction of the display panel;
the first region is an area including the display panel and part of the housing; and
the opening is arranged in the second region.

2. The display device according to claim 1, wherein the first region and the second region are configured in a manner that one side of the lid attached to the opening is in contact with a boundary line between the first region and the second region.

3. The display device according to claim 1, wherein a boundary line between the first region and the second region is configured to extend straight.

4. The display device according to claim 2, wherein the boundary line between the first region and the second region is configured to extend straight.

5. The display device according to claim 1, wherein, of the sheet, an area to be attached to the display panel is transparent and an area to be attached to the housing is colored with a color different from that of the housing.

6. The display device according to claim 1, wherein the sheet has a texture different from that of the housing.
